(19) United States
(12) Patent Application Publication
(10) Pub. No.: US 2003/0121541 A1
(43) Pub. Date: Jul. 3, 2003

(54) Solar powered backlighted building and home identification system

(76) Inventors: Herbert A. Hilton, Key Largo, FL (US); Lin B. Hilton, Key Largo, FL (US)

Correspondence Address: ROBERT C. KAIN, JR., 750 SOUTHEAST THIRD AVENUE, SUITE 100, FT LAUDERDALE, FL, 333161153

(21) Appl. No.: 10/205,383

(22) Filed: Jul. 25, 2002

Related U.S. Application Data
(63) Continuation-in-part of application No. 29/153,192, filed on Jan. 3, 2002, now Pat. No. D469128.

(51) Int. Cl. H01L 31/00

(52) U.S. Cl. 136/244; 136/291

(57) ABSTRACT

The present invention relates to a solar powered backlighted building and home identification system for use in outdoor ambient areas exposed to sunlight. The system includes a substantially closed container having at least one lighted area with opposing rails that define opposite sides of the lighted area. Sliding indicia, used to identify the home or building, are placed between the rails. A solar cell is disposed on the container such that said solar cell is exposed to ambient sunlight during daylight hours. The solar cell charges a battery which is used to energize at least one light bulb disposed within the container to illuminate the lighted area of the container during periods of darkness. A photoelectric cell may be utilized to energize the light bulb only during periods of darkness. The sliding indicia may be changed to display pertinent home or building information.

This is a continuation-in-part patent application based upon and claiming priority of U.S. design patent application Ser. No. 29/153,192, filed Jan. 3, 2000, now pending.

The present invention relates to a solar powered, backlighted building and home identification system.

### BACKGROUND OF THE INVENTION

Most buildings and homes utilize alphanumeric characters or symbols to display the address, location or other information to the public or passersby. Most of these displays are not lighted. Those that are lighted utilize spotlights or are lighted using electrical power supplied from the building or home. There is a need for a solar powered, backlighted building and home identification system which does not depend upon outside sources of electrical energy to provide illumination. There is also a need for an identification system which can be easily adapted to display the address, location or other pertinent information desired by the home or building tenant.

### OBJECTS OF THE INVENTION

It is an object of the present invention to provide a solar powered building and home identification system which includes a display that is backlighted via a light bulb powered by a battery which is charged using a solar cell.

It is another object of the present invention to provide a solar powered identification system which includes more than one backlighted display.

It is a further object of the present invention to provide a solar powered building and home identification system which accommodates changes to the sign via interchangeable or universal indicia panels.

It is a further object of the present invention to provide a solar powered identification system which includes a photoelectric cell such that the identification system illuminates only during periods of darkness.

### SUMMARY OF THE INVENTION

The present invention relates to a solar powered backlighted building and home identification system for use in outdoor ambient areas exposed to sunlight. The system includes a substantially closed container for outdoor use. The container has at least one lighted area with opposing rails that define opposite sides of the lighted area. The system also includes sliding indicia used to identify the home or building. The indicia have extending tabs which fit within respective opposing rails of the lighted area such that the indicia slide within the rails. The system includes a solar cell disposed on the container such that said solar cell is exposed to ambient sunlight during daylight hours. The solar cell charges a battery which is used to energize at least one light bulb disposed within the container to illuminate the lighted area of the container during periods of darkness. A photoelectric cell may be utilized to energize the light bulb only during periods of darkness. The sliding indicia may be sliding indicia panels. The lighted areas may also include a translucent material substantially covering the lighted area such that the sliding indicia slide onto or behind the translucent material.

### BRIEF DESCRIPTION OF THE DRAWINGS

Further objects and advantages of the present invention can be found in the detailed description of the preferred embodiments when taken in conjunction with the accompanying drawings in which:

FIG. 1 diagrammatically illustrates a side view of one embodiment of the solar powered building and home identification system;

FIG. 2 diagrammatically illustrates a top view of the solar powered system;

FIG. 3 diagrammatically illustrates another side view of the system in FIG. 1;

FIG. 4 diagrammatically illustrates a bottom view of the system in FIG. 1;

FIG. 5 diagrammatically illustrates a back view of the system in FIG. 1;

FIG. 6 diagrammatically illustrates a side view of another embodiment of the solar powered building and home identification system in which the solar cells are not visible from the side;

FIG. 7 diagrammatically illustrates a top view of the solar powered system of FIG. 6;

FIG. 8 diagrammatically illustrates another side view of the system in FIG. 6;

FIG. 9 diagrammatically illustrates a bottom view of the system in FIG. 6;

FIG. 10 diagrammatically illustrates a back view of the system in FIG. 6;

FIG. 11 diagrammatically illustrates a side view of another embodiment of the solar powered building and home identification system with one solar cell disposed on top of the identification system container;

FIG. 12 diagrammatically illustrates a top view of the solar powered identification system of FIG. 11;

FIG. 13 diagrammatically illustrates another side view of the system in FIG. 11;

FIG. 14 diagrammatically illustrates a bottom view of the system in FIG. 11;

FIG. 15 diagrammatically illustrates a back view of the system in FIG. 11;

FIG. 16 diagrammatically illustrates a side view of another embodiment of the solar powered building and home identification system with slidable indicia on the illuminated area;

FIG. 17 diagrammatically illustrates the opposite side of the identification system illustrated in FIG. 16;

FIG. 18 diagrammatically illustrates a partial cross-sectional view of the lighted area of the identification system;

FIG. 19 diagrammatically illustrates the use of sliding indicia on the lighted area of the identification system;

FIG. 20 diagrammatically illustrates the use of a different embodiment of the sliding indica for the solar powered building and home identification system; and

FIG. 21 diagrammatically illustrates the internal components of the solar powered identification system.

### DETAILED DESCRIPTION OF THE PREFERRED EMBODIMENTS

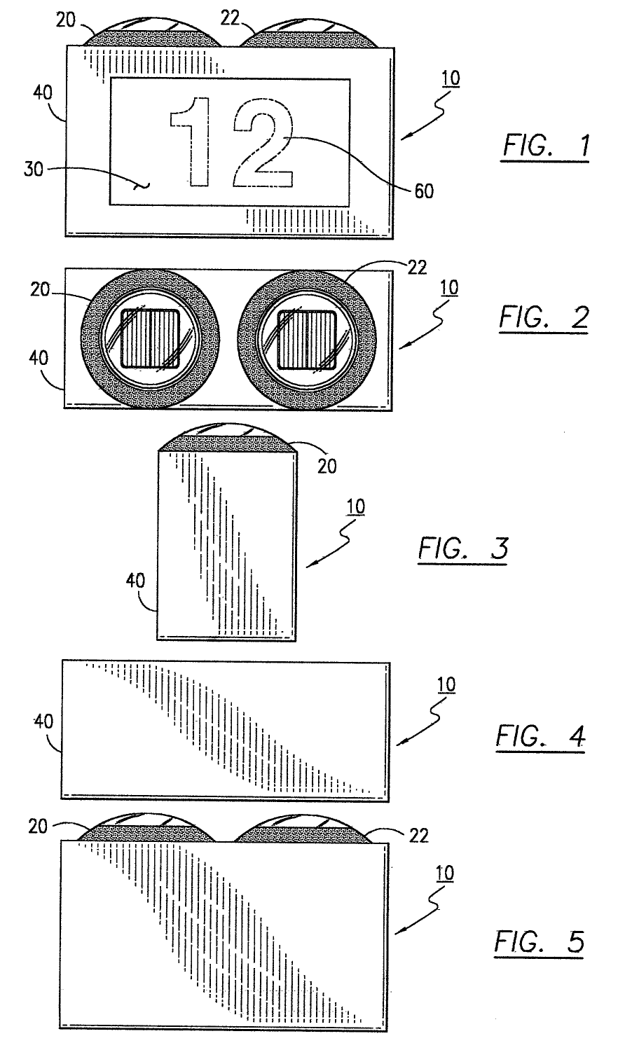

The present invention relates to a solar powered, backlighted building and home identification system for outdoor use. The solar powered building and home identification system 10 is diagrammatically illustrated in FIG. 1. The identification system 10 is designed for use in outdoor ambient areas exposed to sunlight. The identification system illustrated in FIG. 1 includes two solar cells 20, 22 disposed on the top side of the container 40. Container 40 is substantially closed to protect the components inside the container from the ambient weather conditions outside the container. The container may be made of any suitable material, including wood, plastic, or metal. The solar cells 20, 22, also referred to as photoelectric cells or photovoltaic cells, are cells that are able to convert light into electrical energy which are commonly known to those of ordinary skill. Identification system 10 may have one or more solar cells 20, 22 disposed on the container 40.

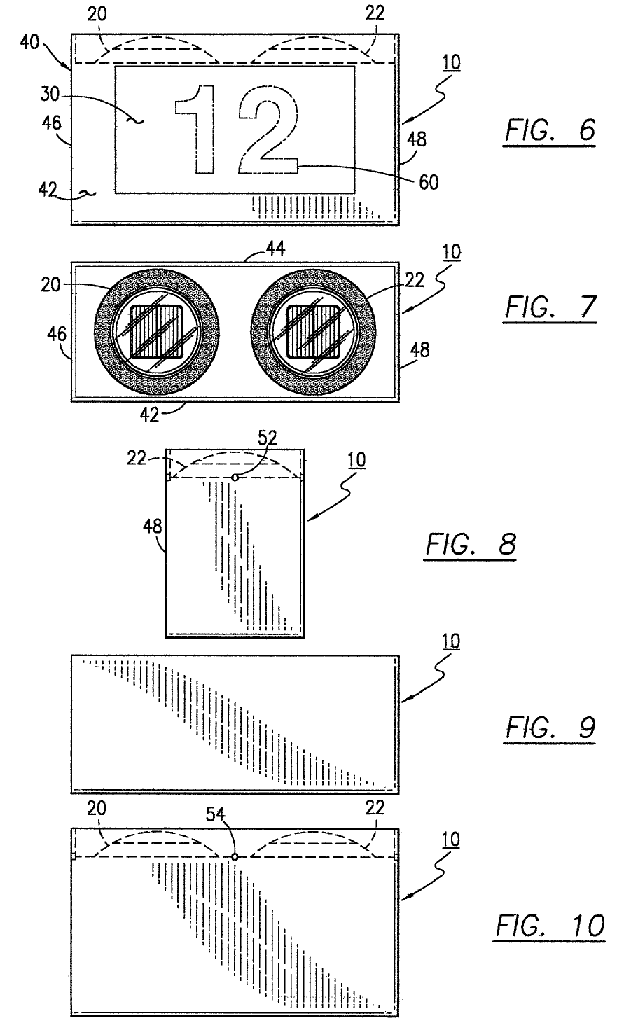

Identification system 10 in FIG. 1 also includes a lighted area 30. Lighted area 30 represents the area of container 40 used to display the identification information. In FIGS. 1 and 6, lighted area 30 contains indicia 60 represented by the alphanumeric characters “12”. Identification system 10 illustrated in FIGS. 1 through 5 only has one lighted area 30. The other sides of container 40 are illustrated in FIGS. 2, 3, 4 and 5. FIG. 2 diagrammatically illustrates a top view of container 40 with solar cells 20, 22 disposed atop the container. In the embodiment illustrated in FIGS. 1 through 5, the solar cells 20, 22 are mounted such that the cells protrude and are visible from a side view. See FIGS. 1, 3 and 5.

FIGS. 6 through 10 diagrammatically illustrate another embodiment of the solar powered building and home identification system 10 in which the solar cells 20, 22 are not visible from the side. In FIG. 6, the solar cells 20, 22 are illustrated in dashed lines. Solar cells 20, 22 are disposed on container 40 such that the side walls 42, 44, 46, 48 of the container form a lip extending upward to hide the solar cells 20, 22 from a side view perspective. In FIGS. 8 and 10, the side walls 48, 44, define small drainage holes 52, 54, respectively, which are designed to permit water that collects atop the container 40 to drain out therefrom.

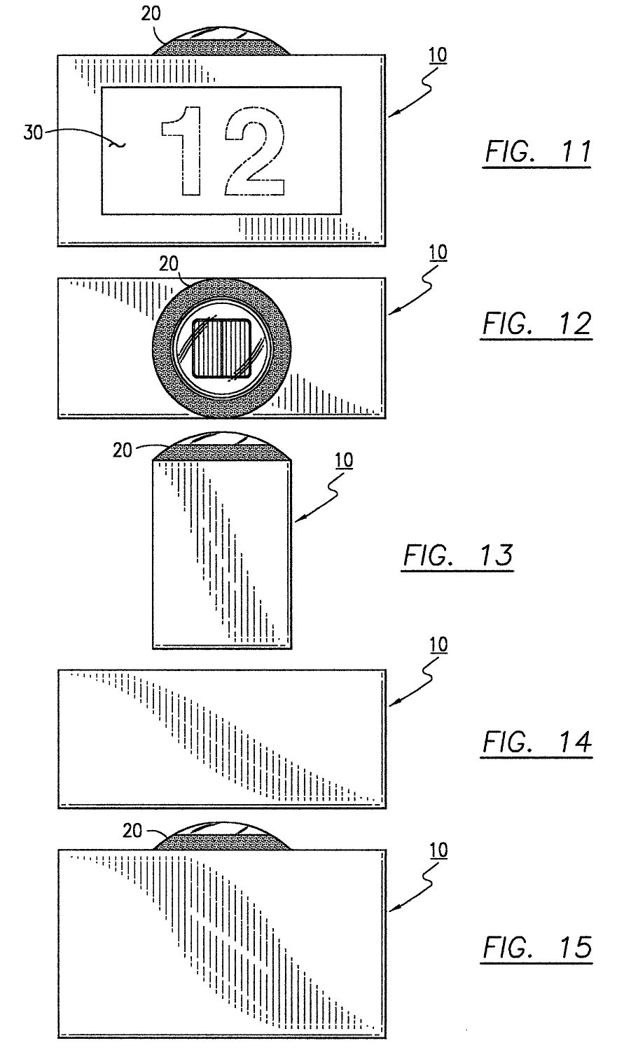

FIGS. 11 through 15 diagrammatically illustrate the solar powered building and home identification system 10 having a single solar cell 20 atop container 40.

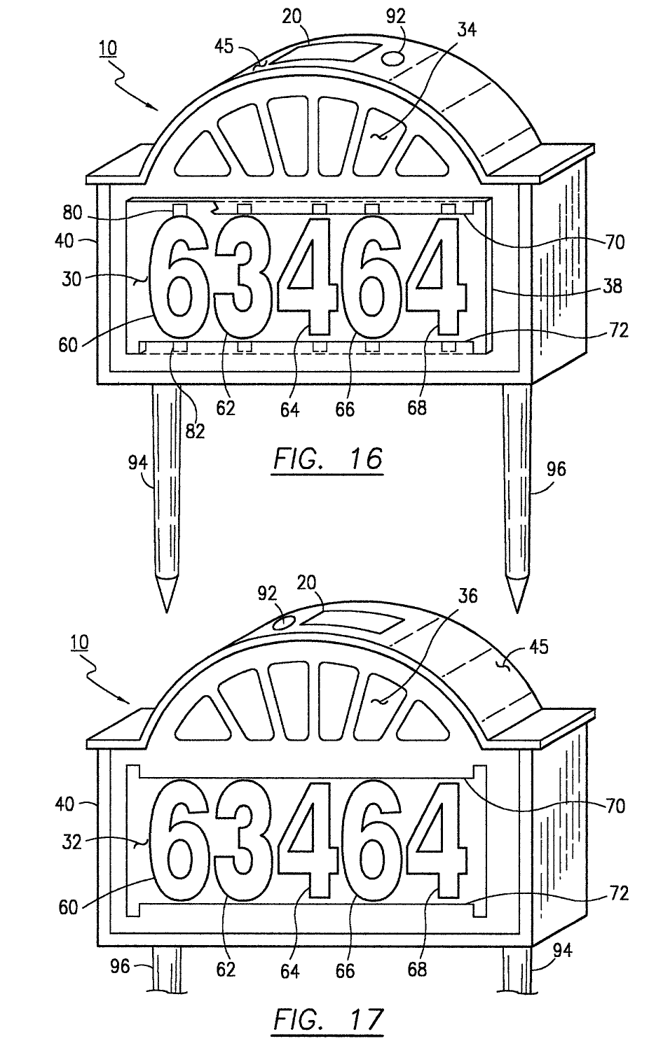

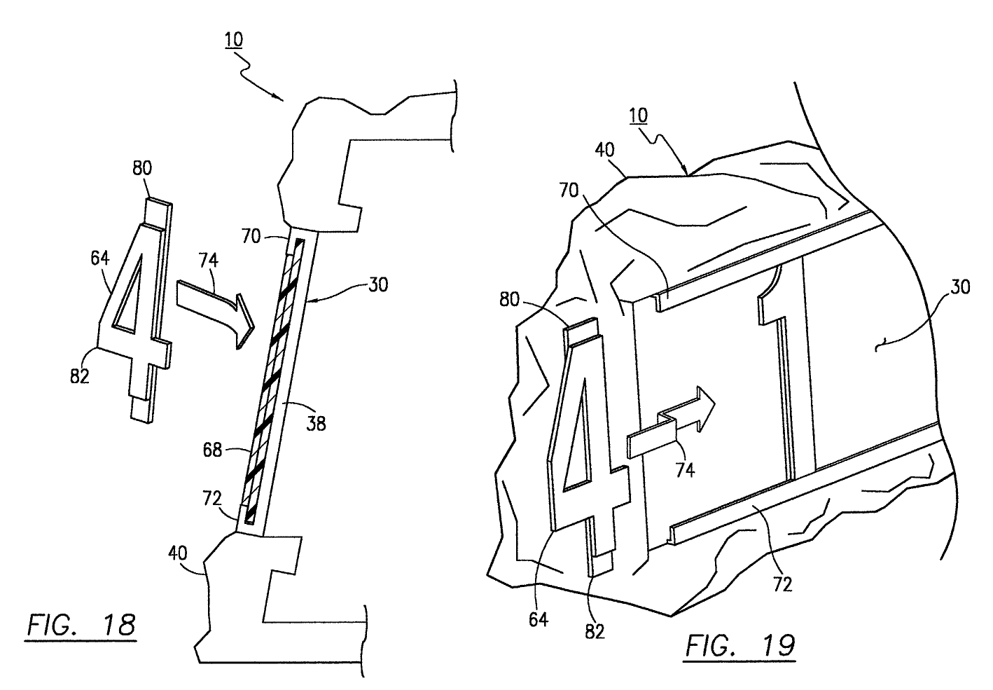

FIGS. 16 and 17 diagrammatically illustrate perspective views of another embodiment of the solar powered identification system 10. The container 40 includes a plurality of lighted display areas 30, 32, 34, 36. FIG. 16 diagrammatically illustrates a front perspective view of the identification system 10, and FIG. 17 the opposite, back perspective view. The container 40 includes a semi-circular or partially-domed top 45. Solar cell 20 is disposed on container 40 such that the solar cell 20 is exposed near the apex of top 45. This position or slightly adjacent the apex of the top 45 is preferred for use of the solar powered identification system 10 in areas where snow may accumulate atop the container 40. The lighted areas 34 above the main lighted display area 30 provides further illumination and artistic flair or style to the identification system 10.

In FIGS. 16 and 17, lighted areas 30, 32 have opposing rails 70, 72 which define opposite sides of the lighted areas 30, 32. FIG. 16 diagrammatically illustrates a partial cutaway view of the opposing rails 70, 72. Lighted areas 30, 32 include indicia 60, 62, 64, 66, 68. Indicia panels or inserts 60, 62, 64, 66 and 68 have extending tabs 80, 82 which slide into opposing rails 70, 72. In FIGS. 16 and 17, lighted areas 30, 32 include a clear or opaque, translucent material 38 upon which indicia 60, 62, 64, 66, 68 overlay. See FIG. 18. Each slidable indicia 60 represents a single alphanumeric character.

The identification system 10 may be utilized in a variety of outdoor locations. The embodiments illustrated in FIGS. 16, 17 and 20 includes downward projecting legs or stakes 94, 96, 98, 100. These embodiments are designed to be placed on or near the ground. The embodiment illustrated in FIG. 19 has a rock-like appearance for placement in a garden area. The home and building identification system 10 may be place anywhere, the only requirement being that the device be exposed to sunlight. Its solar powered characteristic makes identification system 10 ideal for locations where electrical service is not present or too cost prohibitive.

FIG. 18 diagrammatically illustrates a partial cutaway side view of the identification system 10. The lighted area 30 includes a clear or opaque material 38 which may be plastic, glass, acrylic or similar material. The opaque material substantially covers the lighted area and defines the upper and lower rails 70, 72. The indicia 64 slides onto the outside of opaque material 38 viz-a-viz tabs 80, 82 sliding within rails 70, 72, respectively, as indicated by arrow 74. In another embodiment the rails70, 72 may also be placed on the interior side of opaque material 38 such that the indicia are place on the inside.

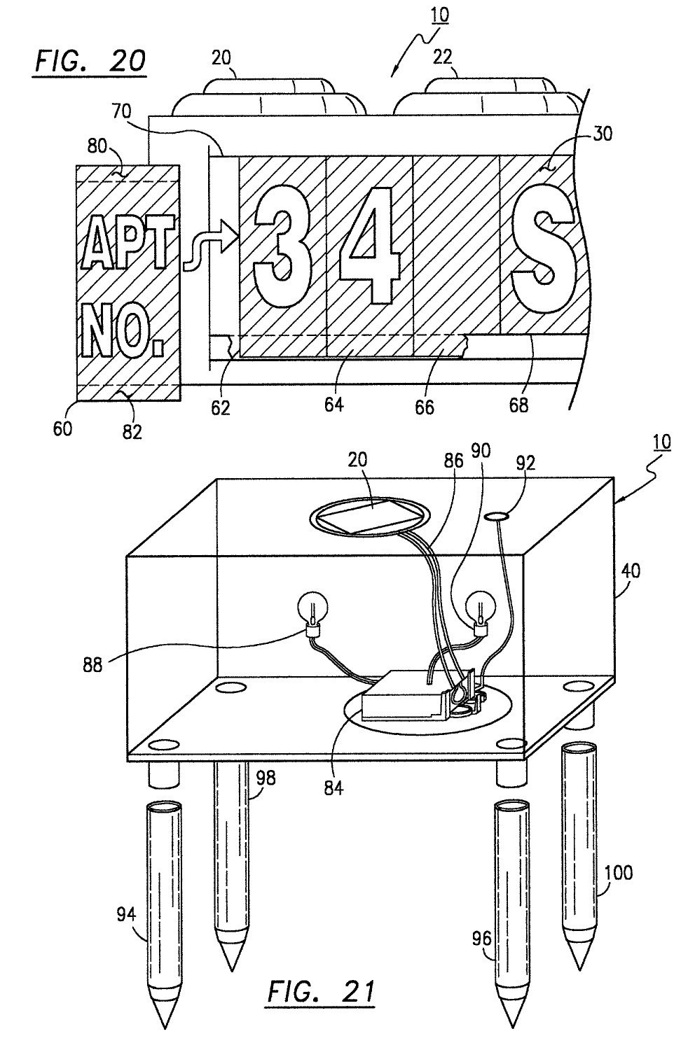

FIG. 19 diagrammatically illustrates alphanumeric indicia 64prior to being inserted into rails 70, 72. In FIG. 19, container 40 has the appearance of a large rock or boulder. Indicia 64 has extending tabs 80, 82 which fit within the gaps defined by rails 70, 72 such that alphanumeric “4” protrudes out from the surface of the lighted area 30. Other indicia panels or inserts may also be used. For example indicia panel 64 may also be a substantially rectangular panel such as that illustrated in FIG. 20. Such indicia panels 60, 62, 64, 66, 68 may also be utilized in connection with the system shown in FIGS. 18 and 19.

FIG. 20 diagrammatically illustrates another embodiment of the sliding indica panels or inserts 60, 62, 64, 66, 68 for the solar powered building and home identification system 10. In FIG. 20, lighted area 30 includes upper and lower rails 70, 72 which also define opposite upper and lower boundaries of the lighted area, respectively. The indicia panels 60, 62, 64, 66, 68 also include extensions or tabs 80, 82 which are used to slide the indicia panels within corresponding rails 70, 72. The indicia panel 60 includes numerous alphanumeric characters which are translucent surrounded by darkened areas. Indicia panels 62, 64 and 68 likewise include a translucent alphanumeric character surrounded by darker areas. Panel 66 is a space filler. Through the use of different indicia panels 60, the building and home identification system may be customized to display the pertinent information. Of course, indicia panels 60, 62, 64, 66, and 68 may also be made such that the alphanumeric characters are darker surrounded by more translucent areas. Because the indicia panels 60, 62, 64, 66 and 68 substantially cover the lighted area 30 in FIG. 20, lighted area 30 does not need a protective clear or opaque material such as translucent lighted panel 38 illustrated in FIG. 18.

FIG. 21 diagrammatically illustrates the internal components of the solar powered identification system 10. Solar cell 20 is electrically coupled to battery 84 via electrical conductors 86. Other components may be added between the solar cells and the battery 84 such as a voltage regulator. Battery 84 may be any electrical storage device, such as a battery-like capacitor, and may include a plurality of rechargeable batteries. Battery 84 may also be electrically coupled to an electrical circuit to monitor the electrical charge in the battery 84 and which may serve to protect the battery bank 84 from overcharging. Although the battery 84 is illustrated as being within container 40, the battery 84 may also be stored externally near or attached to the exterior of container 40.

Identification system 10 includes at least one light bulb 88 electrically coupled to the battery 84. In the embodiment illustrated in FIG. 21, identification system 10 includes two light bulbs 88, 90 disposed within the container 40. Identification system 10 also includes a photoelectric cell 92 electrically coupled to the light bulbs 88, 90 and battery 84. The photoelectric cell 92 is a light detector which is disposed on the container 40 and is used to detect the presence or absence of light outside of container 40. If no light is sensed by photocell 92, then electrical power from battery 84 flows to light bulbs 88 and 92, illuminating the inside of container 40, and thus the lighted areas 30, 32 (FIGS. 16 and 17) are also illuminated. Alternatively, or in conjunction with the photocell, a programmable timer may also be implemented such that the identification system 10 only illuminates during set hours.

The solar powered backlighted building and home identification system 10 is designed to convert sunlight into electrical energy during periods of sunlight. The electrical energy is stored in battery bank 84. During periods of darkness, the light bulbs are energized, illuminating the lighted areas 30 of the identification system 10.

The claims appended hereto are meant to cover modifications and changes within the scope and spirit of the present invention.

What is claimed is:

1. A solar powered backlighted building and home identification system for use in outdoor ambient areas exposed to sunlight comprising:
a substantially closed container for outdoor use, said container having at least one lighted area with opposing rails defining opposite sides of said lighted area;
sliding indicia for identifying said home or building, said indicia having extending tabs slideable within respective opposing rails of said lighted area;
a solar cell disposed on said container such that said solar cell is adapted to be exposed to ambient sunlight during daylight hours;
a battery coupled to and charged by said solar cell;
a light bulb coupled to said battery and disposed within said container to illuminate said lighted area of said container and said indicia during periods of darkness.

2. A solar powered identification system as claimed in claim 1 wherein said solar cell is a plurality of solar cells.

3. A solar powered identification system as claimed in claim 1 wherein said battery is a plurality of batteries.

4. A solar powered identification system as claimed in claim 1 wherein said light bulb is a plurality of light bulbs.

5. A solar powered identification system as claimed in claim 2 wherein said battery is a plurality of batteries.

6. A solar powered identification system as claimed in claim 2 wherein said light bulb is a plurality of light bulbs.

7. A solar powered identification system as claimed in claim 5 wherein said light bulb is a plurality of light bulbs.

8. A solar powered identification system as claimed in claim 1 further comprising a photoelectric cell electrically coupled to said light bulb and said battery such that said light bulb only turns on during periods of darkness.

9. A solar powered identification system as claimed in claim 7 further comprising a photoelectric cell electrically coupled to said light bulbs and said batteries such that said light bulbs only turn on during periods of darkness.

10. A solar powered identification system as claimed in claim 1 wherein said sliding indicia includes a plurality of sliding indicia panels.

11. A solar powered identification system as claimed in claim 10 wherein each indicia panel includes a single alphanumeric symbol.

12. A solar powered identification system as claimed in claim 7 wherein said sliding indicia includes a plurality of sliding indicia panels.

13. A solar powered identification system as claimed in claim 12 wherein each indicia panel includes a single alphanumeric symbol.

14. A solar powered identification system as claimed in claim 9 wherein said sliding indicia includes a plurality of sliding indicia panels.

15. A solar powered identification system as claimed in claim 14 wherein each indicia panel includes a single alphanumeric symbol.

16. A solar powered identification system as claimed in claim 1 wherein said lighted area includes a translucent material and said sliding indicia includes a plurality of sliding indicia panels, each said indicia panel representing a single alphanumeric symbol.

17. A solar powered identification system as claimed in claim 7 wherein said lighted area includes a translucent material and said sliding indicia includes a plurality of sliding indicia panels, each said indicia panel representing a single alphanumeric symbol.

18. A solar powered identification system as claimed in claim 9 wherein said lighted area includes a translucent material and said sliding indicia includes a plurality of sliding indicia panels, each said indicia panel representing a single alphanumeric symbol.

19. A solar powered identification system as claimed in claim 1 wherein said lighted area of said container is at least two lighted areas, each said lighted area having a translucent material and said sliding indicia including a plurality of sliding indicia panels.

20. A solar powered identification system as claimed in claim 7 wherein said lighted area of said container is at least two lighted areas, each said lighted area having a translucent material and said sliding indicia including a plurality of sliding indicia panels.

21. A solar powered identification system as claimed in claim 9 wherein said lighted area of said container is at least two lighted areas, each said lighted area having a translucent material and said sliding indicia including a plurality of sliding indicia panels.
